(19) United States
(12) Patent Application Publication
(10) Pub. No.: US 2025/0326357 A1
(43) Pub. Date: Oct. 23, 2025

(54) CAMERA MONITOR SYSTEM AND VEHICLE WITH CAMERA MONITOR SYSTEM

(71) Applicant: MEKRA Lang GmbH & Co. KG, Ergersheim (DE)

(72) Inventors: Christian TRAUB, Ansbach (DE); Martin SCHUH, Oberdachstetten (DE)

(21) Appl. No.: 19/081,537

(22) Filed: Mar. 17, 2025

(30) Foreign Application Priority Data
Apr. 22, 2024 (DE) 10 2024 111 198.4

(51) Int. Cl. B60R 11/02; B60K 35/22; B60K 35/60

(52) U.S. Cl. CPC B60R 11/0229; B60K 35/22; B60K 35/60; B60K 2360/788; B60R 2300/8046

(57) ABSTRACT

The disclosure relates to a camera monitor system for a vehicle, comprising a camera, a monitor, a monitor holder, and a printed circuit board, wherein the monitor is mechanically installed in the monitor holder and wherein the monitor holder comprises a vehicle interface for mechanical attachment to the vehicle, wherein the printed circuit board is mechanically installed in the monitor holder. The disclosure also relates to a vehicle with such a camera monitor system.

### BACKGROUND

The disclosure relates to a camera monitor system for a vehicle, preferably a utility car or a passenger car. In addition, the disclosure relates to a vehicle, in particular a utility car or passenger car, with a vehicle cabin, a data and/or communication unit and the camera monitor system.

Camera monitor systems for vehicles are already known from the state of the art. In particular, these are used in the field of utility cars. However, such camera monitor systems are also increasingly being used in the field of passenger cars.

Such camera monitor systems have a camera mounted or mountable to the outside of the vehicle in particular as well as a monitor mounted or mountable to the inside of the vehicle in particular. An image region captured by the camera can be displayed on the monitor for a driver of the vehicle.

In addition, the camera monitor systems have a monitor holder for mounting the monitor on or in the vehicle. For this purpose, the monitor holder has a vehicle interface for mechanical attachment to the vehicle and the monitor is mechanically installed in the monitor holder (and is preferably not detachable for a user or the driver).

Different data can be transmitted between the vehicle and the camera monitor system, between individual components of the camera monitor system and/or between the vehicle and the individual components of the camera monitor system. The camera monitor system comprises a printed circuit board (or several printed circuit boards) for processing and/or receiving and/or transmitting this data.

In known camera monitor systems, the printed circuit board is often spatially integrated into a camera wing or a camera housing and/or in the monitor, which, however, leads to larger dimensions and/or a higher weight or an unfavorable weight distribution of the camera wing and/or of the monitor and, in particular, has disadvantages in terms of aerodynamics and exposure to environmental influences due to the external positioning of the camera wing.

Alternatively, the printed circuit board may be arranged as a separate individual component, but this requires more assembly work and takes up additional installation space in the vehicle.

### SUMMARY

It is therefore the object of the disclosure to avoid or at least reduce the disadvantages of the prior art. In particular, a camera monitor system for a vehicle and a vehicle with such a camera monitor system are to be provided, in which the printed circuit board can be positioned particularly advantageously in terms of functionality, manufacturing effort and mountability.

The object of the disclosure is solved by a camera monitor system with the features of claim 1 as well as by a vehicle with the features of the independent claim. Advantageous further embodiments are the subject matter of the dependent claims.

Accordingly, the present disclosure relates to a camera monitor system for a vehicle, preferably a utility car, comprising a camera, a monitor, (at least) one printed circuit board and a monitor holder. The monitor is mechanically installed in the monitor holder, and the monitor holder comprises a vehicle interface for mechanical attachment to the vehicle. According to the disclosure, the printed circuit board is mechanically installed in the monitor holder. The arrangement in the monitor holder makes it possible to avoid having to enlarge the camera wing to accommodate the printed circuit board. At the same time, a simple connection to the monitor and/or to the camera and/or to the vehicle can be established.

According to a preferred embodiment, the printed circuit board (or one of the plurality of printed circuit boards) may be electronically connected to the camera. This means that the printed circuit board has an electronic connection to the camera. This allows data to be transmitted from the printed circuit board to the camera and/or from the camera to the printed circuit board.

According to a preferred embodiment, the printed circuit board (or one of the plurality of printed circuit boards) may be electronically connected to the monitor. This means that the printed circuit board has an electronic connection to the monitor. This allows data to be transmitted from the printed circuit board to the monitor and/or from the monitor to the printed circuit board.

According to a preferred embodiment, the printed circuit board (or one of the plurality of printed circuit boards) may be electronically connected or connectible to the vehicle. This means that the printed circuit board has an electronic connection to the vehicle. This allows data to be transmitted from the printed circuit board to the vehicle and/or from the vehicle to the printed circuit board.

According to a preferred embodiment, the printed circuit board may be mechanically connected directly to the monitor holder, for example via a screw connection, clamp connection, snap connection, and/or material connection. In this way, a suitable mechanical connection can be realized.

According to an alternative preferred embodiment, the camera monitor system may comprise a housing of the printed circuit board which surrounds the printed circuit board. According to the alternative preferred embodiment, the housing of the printed circuit board may be configured separately from the monitor holder and may be mechanically connected to the monitor holder, for example via a screw connection, clamp connection, and/or snap connection. In this way, a suitable mechanical connection can be realized.

According to a further development of the preferred embodiment, the printed circuit board and/or the housing of the printed circuit board may have a plug and/or cable connection for electrical connection to the camera and/or to the monitor and/or to the vehicle.

According to the further development of the preferred embodiment, a plug connection configured on the printed circuit board or on the housing of the printed circuit board may be aligned downward when the camera monitor system is mounted. This additionally prevents water that has penetrated into the camera monitor system from coming into contact with the printed circuit board at the plug connection.

According to a preferred embodiment, the monitor may have a display unit and a monitor housing or monitor cover. In particular, the display unit may comprise a screen or a display panel. In addition, the display unit may comprise a monitor circuit board, for example for receiving a processed image, for preparing a display on the screen, and/or for realizing safety-relevant mechanisms. For example, the monitor circuit board may be installed externally in the monitor holder.

According to a further development of the preferred embodiment, the monitor housing may be configured separately from the monitor holder and may be mechanically connected to the monitor holder, for example via a screw connection, hook connection, and/or bolt connection. In particular, the connection between the monitor housing and the monitor holder may be configured so that it cannot be detached by an end customer/user/driver. This means, for example, that the connection between the monitor housing and the monitor holder can only be detached by the manufacturer in order to replace individual components of the camera monitor system.

According to an alternative embodiment of the preferred embodiment, the monitor housing may be integrally formed by the monitor holder. This means that a rear cover of the monitor is configured by the monitor holder. In particular, the printed circuit board installed in the monitor holder is in this case not exclusively the monitor circuit board, but preferably a printed circuit board with other or additional functions.

According to a preferred embodiment, the vehicle interface may be configured to be mounted on an A-pillar of a vehicle cabin of the vehicle such that (in the vehicle-mounted state of the camera monitor system) the monitor is positioned on a front side of the monitor holder and (in the vehicle-mounted state of the camera monitor system) the A-pillar is positioned on a back side or on a side of the monitor holder. This gives the driver a clear view of the monitor.

According to one embodiment, the monitor holder may form an inner space. This means that the monitor holder forms a cavity for holding components of the camera monitor system. The printed circuit board or the housing of the printed circuit board with the printed circuit board is preferably arranged in the inner space.

According to a preferred embodiment, the monitor holder may comprise a cable guide arranged in the inner space. In particular, the cable guide can serve to fix a cable leading to the monitor (i.e. a cable connected to the monitor) and/or a cable leading to the printed circuit board (i.e. a cable connected to the printed circuit board) and/or a cable leading to the camera (i.e. a cable connected to the camera) and/or a cable leading to the vehicle (i.e. a cable connected to the vehicle). This has the advantage that the positioning of the cable can be fixed and sensible routing of the cable guide can be ensured.

According to a preferred embodiment, the monitor holder may comprise a water drain, in particular on its outer side and/or in its inner space. The water drain may preferably be configured in such a way that water is directed away from the printed circuit board in a targeted manner. This prevents the printed circuit board from coming into contact with water and possibly being damaged as a result.

According to a preferred embodiment, the camera monitor system may comprise a shielding plate for shielding the printed circuit board from EMC interference radiation (electromagnetic compatibility interference radiation). In this way, undesirable mutual influences can be avoided.

According to a further development of the preferred embodiment, the shielding plate may preferably be arranged at least partially or on one side or completely surrounding the printed circuit board. This has the advantage that effective shielding is achieved.

According to a preferred embodiment, the camera monitor system may comprise a heatsink, in particular arranged in the inner space of the monitor holder, for cooling the monitor and/or the printed circuit board. In this way, the printed circuit board and/or the monitor can be protected from overheating and consequently the performance and/or service life can be improved.

According to a further development of the preferred embodiment, the heatsink may be arranged on a side of the printed circuit board opposite the shielding plate. In this way, a suitable weight distribution can be achieved with efficient shielding and cooling.

According to a further development of the preferred embodiment, the heatsink may be attached to the monitor holder mechanically, for example via a screw connection, by hot caulking, by pressing, and/or by overmoulding, preferably with a seal arranged in between. This ensures a reliable and at the same time easily producible mounting.

According to a further development of the preferred embodiment, a thermally conductive element, for example a heat conducting pad or a heat conducting paste, may be arranged between the heatsink and the printed circuit board. This ensures efficient heat transfer. Preferably, the thermally conductive element may be clamped between the heatsink and the printed circuit board and/or may be bonded to the heatsink and/or bonded to the printed circuit board. This prevents unintentional detachment.

According to a further development of the preferred embodiment, the heatsink cannot be visible from the outside (i.e. outside the camera monitor system, in particular the monitor holder) when installed. In particular, the heatsink may be arranged in the inner space of the monitor holder. Such positioning can advantageously shift the center of gravity of the monitor holder toward the mechanical vehicle interface and/or can ensure an appealing external appearance.

According to a preferred embodiment, the camera monitor system may be a mirror replacement system. In particular, the camera monitor system may be a legally approved mirror replacement system. For example, the camera monitor system may be a mirror replacement system approved according to UN/ECE-R46. In particular for such an application, the positioning of the printed circuit boards is of high importance.

According to a preferred embodiment, at least one outer wall of the monitor holder may be made (preferably completely) of plastic. This means that all visible parts of the monitor holder are made of plastic. In this way, a robust monitor holder can be provided that is also easy to manufacture.

According to a preferred embodiment, the printed circuit board or one of the plurality of printed circuit boards may be a processing unit of the camera, i.e. a camera circuit board. The camera circuit board may be used for raw data processing, for example.

According to a preferred embodiment, the printed circuit board or one of the plurality of printed circuit boards may be a processing unit of the monitor, i.e. a monitor circuit board. The monitor circuit board can be used, for example, to receive a processed image and/or to prepare a display on the screen and/or to realize security-related mechanisms.

According to a preferred embodiment, the printed circuit board or one of the plurality of printed circuit boards may be a further processing unit of the camera monitor system, i.e. a printed circuit board of a camera monitor system. The printed circuit board of a camera monitor system can, for example, be used for image recognition. Alternatively or additionally, the further processing unit may represent an electronic vehicle interface.

The disclosure also relates to a vehicle, in particular a utility car, with a vehicle cabin, in particular an A-pillar, a data and/or communication unit, and a camera monitor system as described. In this case, the vehicle interface of the monitor holder is mechanically connected or connectible to the vehicle cabin, in particular to the A-pillar, for example via one or two screws. Alternatively or additionally, the printed circuit board is electronically connected or connectible to the data and/or communication unit, such as a vehicle network, of the vehicle.

In other words, the disclosure relates to a printed circuit board (ECU, electronic control unit) in the monitor holder (i.e. in the monitor holder). The background to this is that the installation space in vehicles is very limited. Until now, printed circuit boards have been available as additional ‘boxes’. Alternatively, the printed circuit boards may be present as central computing units as a separate ‘box’ with housing. In current systems, the computing units/processing units are integrated into the camera wing or the monitor, wherein integration into the camera wing leads to a larger design and higher weight of the camera wing, and is therefore aerodynamically disadvantaged compared to remote sensor heads, i.e. a sensor head with a spatially separate processing unit. In addition, the installation of the printed circuit board on the outside of the vehicle is not advantageous due to the prevailing environmental influences. Furthermore, additional individual components of the system lead to higher assembly costs for the customer. In contrast, integrated systems do not offer the possibility of simply replacing individual components, for example in the event of supply bottlenecks or complaints. The disclosure is therefore based on the problem of finding a solution for additional printed circuit boards that are neither installed directly in the monitor nor in the camera, do not generate any additional assembly work for the customer, and do not require any additional installation space. In particular, the disclosure therefore relates to a monitor holder for a camera monitor system for use in a vehicle, in particular in a utility car, comprising a mechanical attachment of the monitor holder to the vehicle, in particular having a supporting function, for example in the form of screws; a mechanical attachment of a monitor of the camera monitor system to the monitor holder; wherein at least one electronic printed circuit board of the camera monitor system, with at least one electronic connection to the monitor and/or to the camera of the camera monitor system and/or to the vehicle, in particular for power supply, connection to the vehicle network, is mechanically installed in the monitor holder. By installing electronic printed circuit boards of the camera monitor system in the monitor holder, the designs of the camera wing and the monitor can be significantly reduced and, in addition, no further installation space is required for the system. This does not increase the installation effort for the customer. The weight of the monitor may be reduced and the center of gravity of the weight moves further toward the A-pillar, which means that the monitor has to be configured for a lower load compared to (direct) installation of the printed circuit boards in the monitor. This may also reduce vibrations.

### BRIEF DESCRIPTION OF THE DRAWINGS

The disclosure is explained below with the aid of Figures. The following is shown:

FIGS. 1 to 3 show a basic positioning of a camera monitor system and a basic structure of the camera monitor system,

FIGS. 4 and 5 show perspective views of different embodiments of a monitor holder and a monitor of the camera monitor system,

FIGS. 6 to 8 are perspective views of different embodiments of the monitor holder.

The drawings only serve to understand the disclosure. Identical elements are marked with the same reference signs.

### DETAILED DESCRIPTION OF THE INVENTION

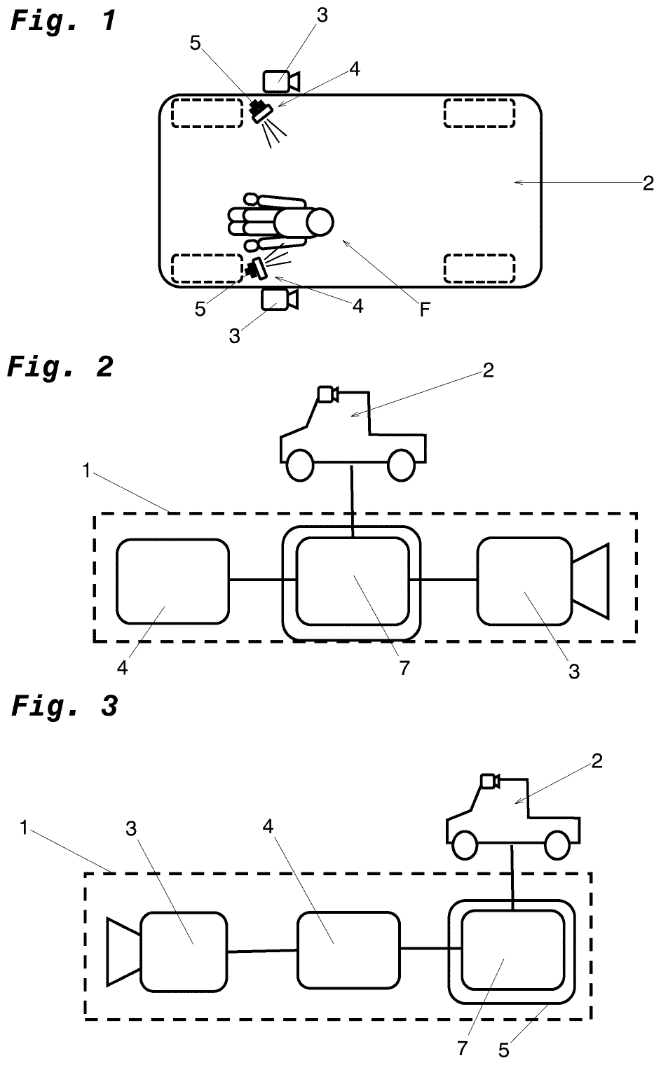

FIGS. 1 to 3 show a camera monitor system 1 for a vehicle 2, in particular a utility car, or a vehicle 2, in particular a utility car, with the camera monitor system 1.

The camera monitor system 1 has a camera 3 with a sensor unit. In particular, the camera 3 is mounted on the outside of the vehicle 2. The camera monitor system 1 has a monitor 4. The monitor 4 is mounted in particular on the inside of the vehicle 2. Preferably, the monitor 4 is aligned so that it can be seen by a driver F. An image region captured by the camera 3 can be displayed on the monitor for the driver F of the vehicle 2.

In particular, the vehicle 2 has two camera monitor systems 1 or a camera monitor system 1 with two cameras 3 mounted on both sides and two monitors 4. In particular, the camera monitor system 1 can serve as a mirror replacement system.

The camera monitor system 1 has a monitor holder 5 for mounting the monitor 4 on or in the vehicle 2. The monitor holder 5 forms a vehicle interface 6 for mechanical attachment to the vehicle 2. The monitor 4 is mechanically installed in the monitor holder 5 or is firmly connected to it.

In addition, the camera monitor system 1 comprises at least one printed circuit board 7. The printed circuit board 7 is a processing and/or computing unit. The printed circuit board 7 (or one of the several printed circuit boards) may be a processing unit of the camera 3, i.e. a camera circuit board, and/or the printed circuit board 7 (or one of the several printed circuit boards) may be a processing unit of the monitor 4, i.e. a monitor circuit board, and/or the printed circuit board 7 (or one of the several printed circuit boards) may be a further processing unit of the camera monitor system, i.e. a printed circuit board of a camera monitor system (see FIG. 2). Alternatively or additionally, the printed circuit board 7 (or one of the several printed circuit boards) may represent an electronic vehicle interface or a data and/or communication interface to the vehicle 2 (see FIG. 3).

According to a central aspect, the printed circuit board 7 is mechanically installed in the monitor holder 5. This means that the printed circuit board 7 is arranged in particular in an inner space of the monitor holder 5. In particular, the printed circuit board 7 is electronically connected or connectable to the camera 3 and/or to the monitor 4, and/or to the vehicle 2.

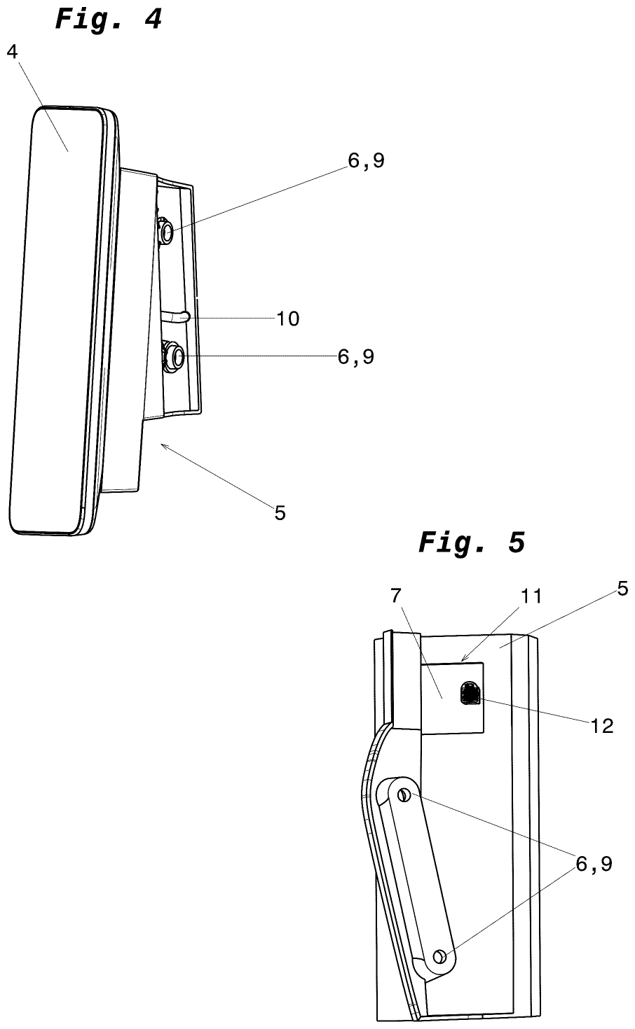

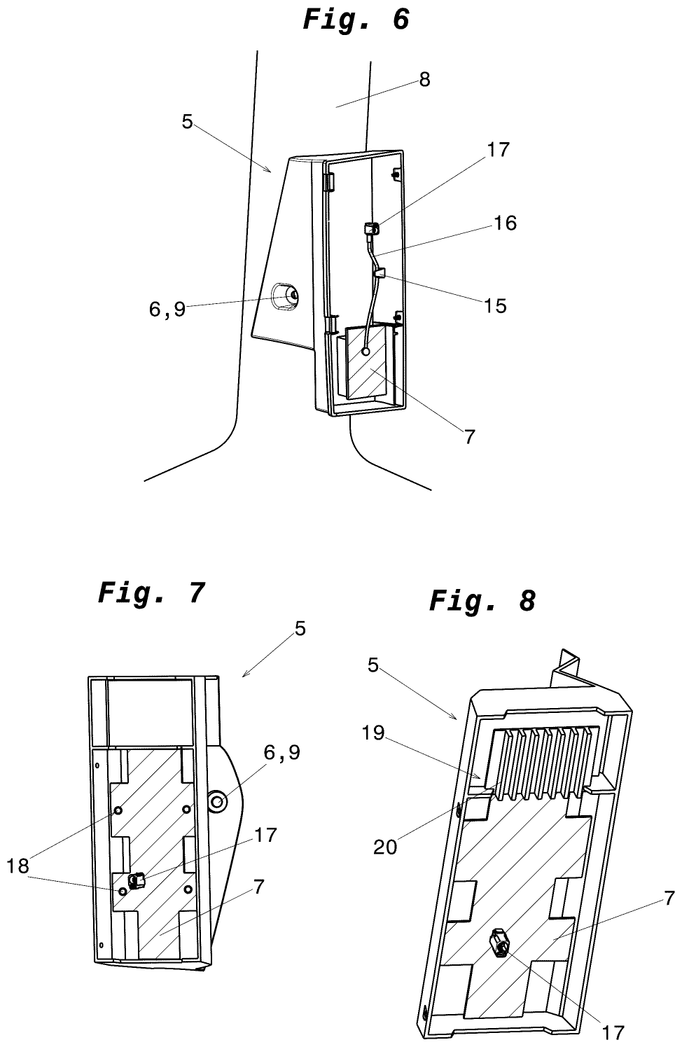

FIGS. 4 and 5 show different embodiments of the monitor holder 5 with the monitor 4 attached thereto. In the state mounted on the vehicle 2, the monitor 4 is positioned on a front side of the monitor holder 5. The vehicle interface 6 is positioned in such a way that a vehicle cabin, in particular an A-pillar 8, of the vehicle 2, which serves as a counter interface, is on a back side of the monitor holder 5 (see FIG. 6).

In FIG. 4, the vehicle interface 6 is formed by two screw holes 9 to the A-pillar 8. A cable connection 10 serves, for example, as an electronic or electrical connection between the printed circuit board 7 and the camera 3 and/or the vehicle 2 and/or the monitor 4.

In FIG. 5, the vehicle interface 6 is formed by the two screw holes 9 to the A-pillar 8. The printed circuit board 7 is arranged in a housing recess 11 of the monitor holder 5 or is accessible from the outside through the housing recess 11. The housing recess 11 is arranged on one side of the monitor holder 5, which is aligned in the direction of the A-pillar 8. A plug connector 12 to the A-pillar 8 is arranged on the printed circuit board 7.

FIGS. 6 to 8 show different embodiments of the monitor holder 5.

In FIG. 6, the mechanical vehicle interface 6 is formed by the screw hole 9 to the A-pillar 8. The printed circuit board 7 is installed directly in the monitor holder 5. Alternatively, the printed circuit board 7 may also be arranged inside a housing of the printed circuit board (separate from the monitor holder 5), even if this is not shown. This means that the printed circuit board 7 may be surrounded within the monitor holder 5 by the additional housing of the printed circuit board. The housing of the printed circuit board may be mechanically connected to the monitor holder 5, for example via screws or another connection. A cable guide 15 in the form of retaining clips is arranged in the inner space of the monitor holder 5. A cable connection 16 is used for the electronic or electrical connection with the monitor 4. The monitor 4 is connected via an electrical plug connection 17.

In FIG. 7, the vehicle interface 6 is formed by the screw hole 9 to the A-pillar 8. The printed circuit board 7 is connected directly to the monitor holder 5 via screw holes 18. The electrical plug connection 17 for attaching the monitor 4 is arranged directly (i.e. without cable feed) on the printed circuit board 7.

In FIG. 8, the printed circuit board 7 is connected directly to the monitor holder 5. The electrical plug connection 17 for attaching the monitor 4 is arranged directly (i.e. without a cable feed) on the printed circuit board 7. In addition, the camera monitor system 1 has a heatsink 19 for cooling the printed circuit board 7 and/or the monitor 4. The heatsink 19 has (in the mounted state of the monitor holder 5) cooling ribs 20 aligned in the vertical direction.

1. A camera monitor system for a vehicle, comprising
a camera,
a monitor holder, the monitor holder comprising, a vehicle interface for mechanical attachment to the vehicle,
a monitor, the monitor being mechanically installed in the monitor holder, and
a printed circuit board, the printed circuit board being mechanically installed in the monitor holder.

2. The camera monitor system according to claim 1, wherein the printed circuit board is electronically connected to the camera.

3. The camera monitor system according to claim 1, wherein the printed circuit board is electronically connected to the monitor.

4. The camera monitor system according to claim 1, wherein the printed circuit board is electronically connected or connectible to the vehicle.

5. The camera monitor system according to claim 1, wherein the printed circuit board is mechanically connected directly to the monitor holder.

6. The camera monitor system according to claim 1, wherein the camera monitor system comprises a housing of the printed circuit board which at least partially surrounds the printed circuit board and which is configured separately from the monitor holder and is mechanically connected to the monitor holder.

7. The camera monitor system according to claim 1, wherein the monitor comprises a display unit and a monitor housing, wherein the monitor housing is configured separately from the monitor holder and is mechanically connected to the monitor holder.

8. The camera monitor system according to claim 1, wherein the monitor comprises a display unit and a monitor housing, wherein the monitor housing is integrally formed by the monitor holder.

9. The camera monitor system according to claim 1, wherein the vehicle interface is configured to be mounted on an A-pillar of a vehicle cabin of the vehicle such that, in the state of the camera monitor system mounted on the vehicle, the monitor is positioned on a front side of the monitor holder and the A-pillar is positioned on a back side or on a side of the monitor holder.

10. The camera monitor system according to claim 1, wherein the monitor holder comprises a water drain.

11. The camera monitor system according to claim 10, wherein the water drain is configured in such a way that water is directed away from the printed circuit board in a targeted manner.

12. The camera monitor system according to claim 1, wherein the camera monitor system comprises a shielding plate for shielding the printed circuit board from EMC interference radiation.

13. The camera monitor system according to claim 1, wherein the camera monitor system comprises a heatsink for cooling the monitor and/or the printed circuit board.

14. The camera monitor system according to claim 13, wherein the heatsink is arranged in an inner space of the monitor holder.

15. The camera monitor system according to claim 1, wherein the camera monitor system is a mirror replacement system.

16. The camera monitor system according to claim 1, wherein the camera monitor system is a legally approved mirror replacement system.

17. The camera monitor system according to claim 1, wherein the camera monitor system is a mirror replacement system approved according to UN/ECE-R46.

18. The camera monitor system according to claim 1, wherein the printed circuit board is a processing unit of the camera, and/or a processing unit of the monitor, and/or a further processing unit of the camera monitor system.

19. A vehicle, comprising
a vehicle cabin, and
a camera monitor system according to claim 1,
wherein the vehicle interface of the monitor holder is mechanically connected or connectible to the vehicle cabin.

20. The vehicle according to claim 19, the vehicle comprising a data and/or communication unit, wherein the printed circuit board is electronically connected or connectible to the data and/or communication unit of the vehicle.
